(19) United States
(12) Patent Application Publication
(10) Pub. No.: US 2016/0222510 A1
(43) Pub. Date: Aug. 4, 2016

(54) PROCESS GAS SUPPLIER

(71) Applicant: TGO Tech. Corporation, Gyeonggi-do (KR)

(72) Inventors: Se Hun YEON, Gyeonggi-do (KR); Yoo Jin LEE, Gyeonggi-do (KR); Jae Hak LEE, Seoul (KR)

(21) Appl. No.: 15/008,975

(22) Filed: Jan. 28, 2016

(30) Foreign Application Priority Data
Jan. 30, 2015 (KR) 10-2015-0014758

(51) Int. Cl. C23C 16/455; C23C 16/22

(52) U.S. Cl. CPC C23C 16/455; C23C 16/22

(57) ABSTRACT

A process gas supplier includes an outer tube providing a passage for a first process gas, a first inner tube in the outer tube and providing a passage for a second process gas, a gas reactor at an upper part of the outer tube, accommodating a metal source and generating a third process gas by a reaction between the second process gas and the metal source, a second inner tube in the outer tube and providing a passage for the third process gas, a third inner tube in the outer tube and providing a passage for a fourth process gas, a first gas injector supplying the first process gas to a processing space outside the outer tube, a second gas injector supplying the third process gas to the processing space, and a third gas injector supplying the fourth process gas to the processing space.

### CROSS-REFERENCE TO RELATED PATENT APPLICATION

This application claims the benefit of Korean Patent Application No. 10-2015-0014758, filed on Jan. 30, 2015, in the Korean Intellectual Property Office, the disclosure of which is incorporated herein in its entirety by reference.

### BACKGROUND

1. Field

The disclosure relates to a process gas supplier and, more particularly, to a process gas supplier capable of supplying three types of gases to a processing space using a single nozzle.

2. Description of the Related Art

A light emitting diode (LED) is a semiconductor device for converting current into light, and is widely used as a light source for displaying an image in electronic devices including information and communication devices. Particularly, compared to a conventional lighting device such as an incandescent lamp or a fluorescent lamp, the LED device is capable of reducing energy consumption by up to 90% due to a high efficiency of converting electrical energy into light energy, and thus is broadly regarded as a substitute for the incandescent lamp or the fluorescent lamp.

A manufacturing process of the LED device may be largely divided into an epitaxial process, a chip process, and a package process. The epitaxial process refers to a process for epitaxially growing a compound semiconductor on a substrate, the chip process refers to a process for producing an epitaxial chip by forming electrodes on parts of the epitaxially grown substrate, and the package process refers to a process for connecting a lead to the produced epitaxial chip and packaging the epitaxial chip to emit light as much as possible.

Among the above processes, the epitaxial process may be the most significant process which determines emission efficiency of the LED device, because defects are generated in crystals if the compound semiconductor is not epitaxially grown on the substrate and serve as nonradiative centers to lower the emission efficiency of the LED device.

The epitaxial process, i.e., the process for forming an epitaxial layer on the substrate, is performed using liquid phase epitaxy (LPE), vapor phase epitaxy (VPE), molecular beam epitaxy (MBE), chemical vapor deposition (CVD), or the like. Specifically, metal-organic chemical vapor deposition (MOCVD) or hydride vapor phase epitaxy (HVPE) is commonly used.

For this process, an epitaxial layer forming apparatus includes a process gas supplier for supplying a process gas reacting to form the epitaxial layer on the substrate, and a basic function of the process gas supplier is to stably supply the process gas.

FIG. 1 is a cross-sectional view of a conventional deposition layer forming apparatus 10, and FIG. 2 illustrates a conventional process gas supplier 40. (a) of FIG. 2 is a perspective view of the process gas supplier 40, (b) of FIG. 2 is a transparent perspective view of the process gas supplier 40, and (c) of FIG. 2 is a cross-sectional view of the process gas supplier 40.

Referring to FIG. 1, the conventional deposition layer (epitaxial layer) forming apparatus 10 may include a chamber 20, a plurality of substrate holders 30, the process gas supplier 40, and a metal halogen gas generator 60.

The chamber 20 has a rectangular or circular shape and provides a space for forming deposition layers. The substrate holders 30 are stacked on one another with intervals therebetween. The process gas supplier 40 is provided to penetrate through central through holes (not shown) of the substrate holders 30, and supplies process gases g′: g1′ and g3′ required to form deposition layers, into the chamber 20.

Referring to FIG. 2, the process gas supplier 40 may have a double tube shape including an outer tube 41 and one or more inner tubes 42 located inside the outer tube 41. The outer tube 41 may be used to supply a metal halogen gas g3′ (e.g., a GaCl gas) through first gas supplying holes 44 into the chamber 20, and the inner tubes 42 may be used to supply a nitriding gas g1′ (e.g., an NH₃ gas) through second gas supplying holes 43 into the chamber 20.

The conventional deposition layer forming apparatus 10 may receive the metal halogen gas g3′ supplied from the metal halogen gas generator 60. The metal halogen gas generator 60 includes a halogen-containing gas supplier 61 and a metal halogen gas supplier 62 provided at two ends of the metal halogen gas generator 60, and a metal source container 65 for accommodating a metal source 66 therein. A halogen-containing gas g2′ (e.g., an HCl gas) supplied through the halogen-containing gas supplier 61 into the metal halogen gas generator 60 may react the metal source 66 of the metal source container 65 to generate the metal halogen gas g3′. The metal halogen gas g3′ may be discharged through the metal halogen gas supplier 62 and may be supplied through a transfer tube 50 to the process gas supplier 40.

The above-described conventional deposition layer forming apparatus 10 additionally includes the metal halogen gas generator 60 outside the chamber 20 to generate the metal halogen gas g3′. As an example of the metal halogen gas g3′, GaCl is liquefied or condensed at 600° C. or below and thus the process gas supplier 40 for supplying GaCl should be maintained at a temperature higher than 600° C. However, since the metal halogen gas generator 60 is provided outside the chamber 20, the metal halogen gas generator 60 is not easily maintained at a high temperature, GaCl is liquefied or condensed in the process gas supplier 40, and thus the GaCl gas is not stably supplied into the chamber 20. In addition, since the metal halogen gas generator 60 is additionally provided outside the chamber 20, an apparatus size is increased.

Furthermore, in the structure of the process gas supplier 40 of the conventional deposition layer forming apparatus 10, since only two types of gases (e.g., a GaCl gas and an NH₃ gas) are suppliable, a doping gas (e.g., a SiH₄ gas) should be mixed with another gas to supply the same. If a doping gas supply tube (not shown) is additionally provided to solve the above problem, the whole design inside the chamber 20 should be changed to avoid interference.

Besides, in the structure of the process gas supplier 40 of the conventional deposition layer forming apparatus 10, since the first and second gas supplying holes 44 and 43 supply gases into the chamber 20 in different directions (see FIG. 2(c)), i.e., since the first and second gas supplying holes 44 and 43 are alternately provided along the outer circumferential surface of the chamber 20, a reaction rate of reaction gases, i.e., the GaCl gas g3′ and the NH₃ gas g1′, may not be easily controlled to be uniform.

### SUMMARY

The disclosure provides a process gas supplier capable of stably supplying process gases and reducing an apparatus size.

The disclosure also provides a process gas supplier capable of simultaneously supplying three types of gases.

The disclosure also provides a process gas supplier capable of supplying process gases to achieve a uniform reaction rate.

According to an aspect of the present invention, there is provided a process gas supplier including an outer tube providing a passage for a first process gas, a first inner tube located in the outer tube and providing a passage for a second process gas, a gas reactor located at an upper side of the outer tube, accommodating a metal source and generating a third process gas by a reaction between the second process gas and the metal source, a second inner tube located in the outer tube and providing a passage for the third process gas, a third inner tube located in the outer tube and providing a passage for a fourth process gas, one or more first gas injectors supplying the first process gas flowing in the outer tube, to a processing space outside the outer tube, one or more second gas injectors supplying the third process gas flowing in the second inner tubes, to the processing space, and one or more third gas injectors supplying the fourth process gas flowing in the third inner tubes, to the processing space.

### BRIEF DESCRIPTION OF THE DRAWINGS

The above and other features and advantages of the disclosed technology will become more apparent by describing in detail embodiments thereof with reference to the attached drawings in which:

FIG. 1 is a cross-sectional view of a conventional deposition layer forming apparatus;

FIG. 2 illustrates a conventional process gas supplier;

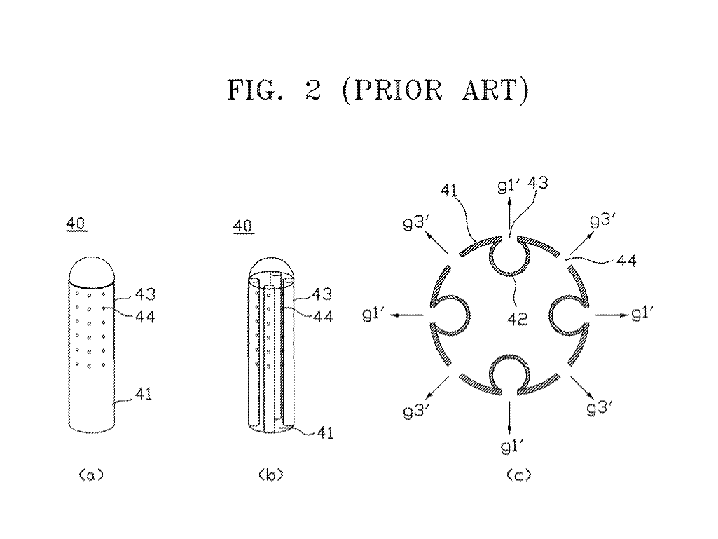

FIG. 3 is a cross-sectional view of a batch-type deposition layer forming apparatus according to an embodiment of the present invention;

FIG. 4 is a perspective view of a process gas supplier according to an embodiment of the present invention;

FIG. 5 is a vertical cross-sectional view of the process gas supplier an embodiment of the present invention; and

FIG. 6 is a horizontal cross-sectional view of the process gas supplier an embodiment of the present invention.

### DETAILED DESCRIPTION

In the following detailed description, reference is made to the accompanying drawings that show, by way of illustration, specific embodiments in which the invention may be practiced. These embodiments are described in sufficient detail to enable those skilled in the art to practice the invention. It is to be understood that the various embodiments of the invention, although different, are not necessarily mutually exclusive. For example, a particular feature, structure, or characteristic described herein in connection with one embodiment may be implemented within other embodiments without departing from the spirit and scope of the invention. In addition, it is to be understood that the location or arrangement of individual elements within each disclosed embodiment may be modified without departing from the spirit and scope of the invention. The following detailed description is, therefore, not to be taken in a limiting sense, and the scope of the present invention is defined only by the appended claims, appropriately interpreted, along with the full range of equivalents to which the claims are entitled. In the drawings, like numerals refer to the same or similar functionality throughout the several views.

### Embodiments of the Present Invention

Hereinafter, the present invention will be described in detail by explaining embodiments of the invention with reference to the attached drawings.

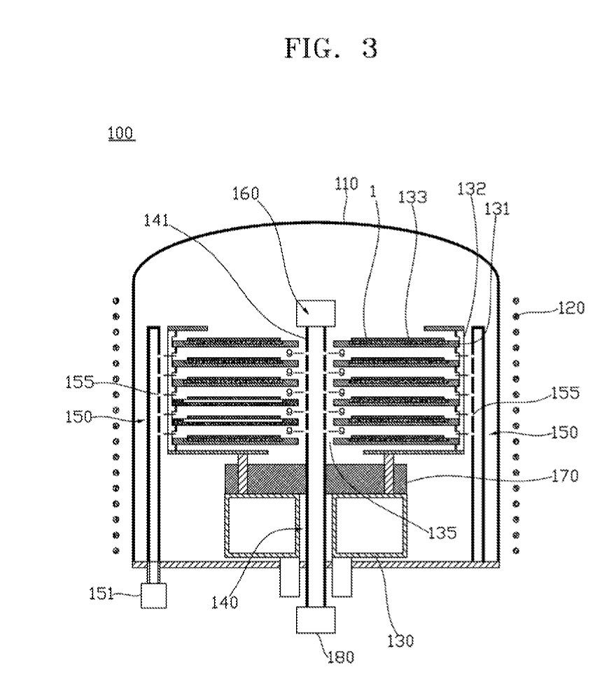

FIG. 3 is a cross-sectional view of a batch-type deposition layer forming apparatus 100 according to an embodiment of the present invention.

A plurality of substrates 1 loaded in the batch-type deposition layer forming apparatus 100 is not limited to a specific material and may be formed of various materials such as glass, plastic, polymer, silicon wafer, stainless steel, and sapphire. The following description assumes the substrates 1 as circular sapphire substrates used in the field of light-emitting diodes (LEDs).

Referring to FIG. 3, the batch-type deposition layer forming apparatus 100 according to the current embodiment of the present invention is configured to include a chamber 110. The chamber 110 may be configured to seal an internal space thereof during processes and may provide a space for forming deposition layers (epitaxial layers) on the substrates 1. The chamber 110 may be configured to maintain an optimal process condition and may be produced in a rectangular or circular shape. The chamber 110 may be formed of quartz but is not limited thereto.

Referring further to FIG. 3, the batch-type deposition layer forming apparatus 100 according to the current embodiment of the present invention may be configured to include a heater 120. The heater 120 may be provided outside the chamber 110 to apply heat required for an epitaxial process, to the substrates 1. For appropriate epitaxial growth on the substrates 1, the heater 120 may heat the substrates 1 to a temperature equal to or higher than about 1,200° C.

In the embodiment, the substrates 1 may be heated using a halogen lamp or a resistive heating element and, preferably, using induction heating. Induction heating refers to a scheme of heating a conductive object such as metal using electromagnetic induction. To use induction heating, the heater 120 may be configured as a coil-type heater capable of induction-heating the internal space of the chamber 110, and a plurality of susceptors 133 provided on a plurality of substrate supports 131 may be configured to include a conductive material. The substrates 1 may be heated using the coil-type heater 120 based on a principle that the susceptors 133 including a conductive material is heated as a high-frequency alternating current is applied from the coil-type heater 120 into the chamber 110.

When the substrates 1 are heated using induction heating as described above, elements of the batch-type deposition layer forming apparatus 100 other than the susceptors 133 may be formed of a nonconductor (e.g., quartz). As such, since only the susceptors 133 are heated by the coil-type heater 120, deposition on the other elements inside the chamber 110 may be minimized.

Referring further to FIG. 3, the batch-type deposition layer forming apparatus 100 according to the current embodiment of the present invention may be configured to include a lower holder 130. The lower holder 130 may be provided inside the chamber 110 to support the substrates 1 during the epitaxial process.

The lower holder 130 may be configured to be rotatable inside the chamber 110. To make the lower holder 130 rotatable, the lower holder 130 may employ a variety of known rotary force generators. As the lower holder 130 rotates inside the chamber 110, the substrate supports 131 of the lower holder 130 also rotate. As such, concentration of process gases g: g1, g3, and g4 at certain locations of the substrates 1 may be prevented. Consequently, the process gases g may be uniformly supplied onto the substrates 1.

Referring to FIG. 3, the lower holder 130 may be configured to include the substrate supports 131 for mounting the substrates 1 thereon. As illustrated in FIG. 3, the substrate supports 131 may be configured in the form of circular plates for appropriate rotation of the lower holder 130, but are not limited thereto.

Referring further to FIG. 3, the substrate supports 131 may be stacked on one another with intervals therebetween. In this case, the substrate supports 131 may be connected and fixed to each other by a connection member 132. The number of the substrate supports 131 is six in FIG. 3 but is not limited thereto. The number of the substrate supports 131 may be variously changed depending on a purpose of the embodiments. The substrate supports 131 may be formed of quartz but are not limited thereto.

As will be described below, in the embodiment, a process gas supplier 140 penetrating through the centers of the substrate supports 131 of the lower holder 130 supplies the process gases g. In this case, as the process gases g are supplied from the centers of the substrate supports 131, the amount of the process gases g supplied to portions of the substrates 1 near the centers of the substrate supports 131 may be greater than that supplied to the other portions. To solve this problem, the substrates 1 mounted on the substrate supports 131 may independently rotate. In other words, the substrates 1 may separately rotate in parallel to the substrate supports 131 at different rotation speeds or in different rotation directions during the epitaxial process. The independent rotation of the substrates 1 may be performed due to rotation of the susceptors 133 for mounting the substrates 1 thereon. As the substrates 1 independently rotate, the process gases g may be uniformly supplied onto the substrates 1.

Referring further to FIG. 3, the susceptors 133 may be individually mounted on the substrate supports 131. The susceptors 133 may support and prevent deformation of the substrates 1 during the epitaxial process. The number of the susceptors 133 mounted on the substrate supports 131 may equal the number of the substrates 1 provided on the substrate supports 131.

In addition to the function of preventing deformation of the substrates 1, the susceptors 133 may heat the substrates 1 together with the coil-type heater 120 as described above. To this end, the susceptors 133 may be formed of a conductive material, e.g., amorphous carbon, diamondlike carbon, or glasslike carbon, and, preferably, of graphite. Graphite has a high strength and an excellent conductivity, and thus may be appropriately heated using induction heating. When the susceptors 133 are formed of graphite as described above, the surface of graphite may be coated with silicon carbide (SiC). Since SiC has an excellent high-temperature strength and hardness and a high thermal conductivity, dispersion of graphite molecules during heating may be prevented and heat may be easily transferred to the substrates 1.

In addition to the function of preventing deformation of the substrates 1 and the function of heating the substrates 1, the susceptors 133 may allow the substrates 1 to rotate as described above. To this end, the susceptors 133 may employ a variety of known rotary force generators. Furthermore, the susceptors 133 may be configured in the form of circular plates for appropriate rotation, but are not limited thereto and may have a variety of shapes depending on a purpose of the embodiments.

Referring further to FIG. 3, the batch-type deposition layer forming apparatus 100 according to the current embodiment of the present invention may be configured to include the process gas supplier 140. The process gas supplier 140 may supply the process gases g required to form epitaxial layers, into the chamber 110.

As illustrated in FIG. 3, in the embodiment, the process gas supplier 140 may be provided to penetrate the centers of the substrate supports 131. In other words, as the process gas supplier 140 are provided to penetrate through central through holes 135 of the substrate supports 131, the process gases g may be supplied from the centers of the substrate supports 131 toward the substrates 1 supported by the substrate supports 131. By employing this configuration, the process gases g may be uniformly supplied onto the substrates 1 and thus epitaxial layers having the same quality and thickness may be formed on the substrates 1.

In addition, the process gas supplier 140 may rotate during the epitaxial process. To rotate the process gas supplier 140, the process gas supplier 140 may employ a variety of known rotary force generators. As such, concentration of the process gases g at certain locations of the substrates 1 may be prevented similarly to the effect achieved due to rotation of the lower holder 130. Consequently, the process gases g may be uniformly supplied onto the substrates 1.

Referring to FIG. 3, a process gas discharger 150 may discharge the process gases g to the outside of the chamber 110. The process gas discharger 150 may be provided in a cylindrical shape surrounding the substrate supports 131. A plurality of discharge holes 155 for discharging the process gases g may be provided in the process gas discharger 150 to correspond to the substrate supports 131. The discharge holes 155 may be configured as slits but are not limited thereto. In addition, the number of the discharge holes 155 may be variously changed depending on a purpose of the embodiments.

A suction means 151 capable of sucking out the process gases g may be connected outside the process gas discharger 150 to discharge the process gases g from the discharge holes 155 to the outside of the chamber 110. The discharge holes 155 may be located near the substrate supports 131. By employing this configuration, the process gases g injected from the process gas supplier 140 may directly flow into the discharge holes 155 without circulating in the chamber 110 and thus excessive supply of the process gases g onto the substrates 1 may be minimized. Consequently, the process gases g may be uniformly supplied onto the substrates 1. The discharge holes 155 may be provided with equal intervals therebetween in a horizontal direction for uniform flow of the process gases g.

A baffle 170 may be located under the substrate supports 131 to prevent leakage of heat generated in the chamber 110 and, more particularly, to prevent leakage of heat through the lower holder 130.

A rotator 180 allows the process gas supplier 140 to rotate and may be located under the process gas supplier 140.

A detailed description is now given of the structure of the process gas supplier 140 used in the batch-type deposition layer forming apparatus 100, according to an embodiment of the present invention. The following description assumes that the process gas supplier 140 uses GaCl, NH₃, and SiH₄ gases as the process gases g: g1, g3, and g4 to form epitaxial gallium nitride (GaN) layers on the substrates 1 using hydride vapor phase epitaxy (HVPE), but is not limited thereto.

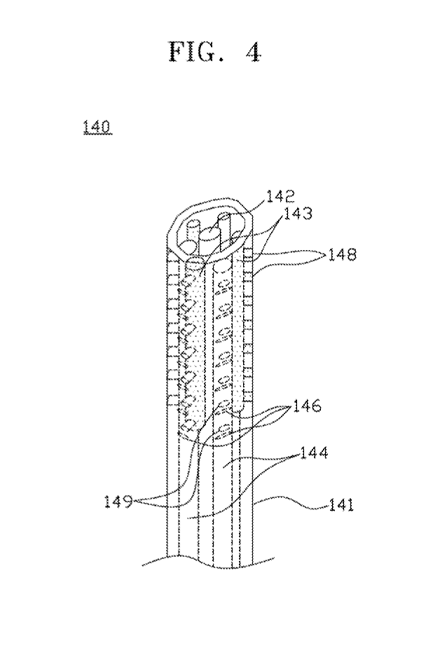

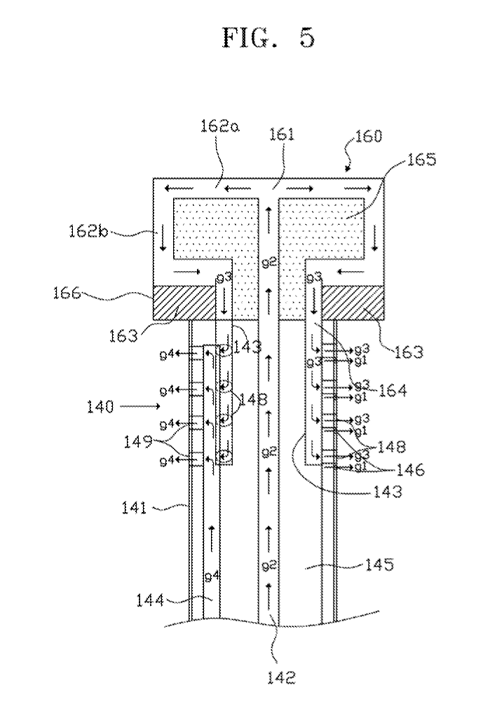

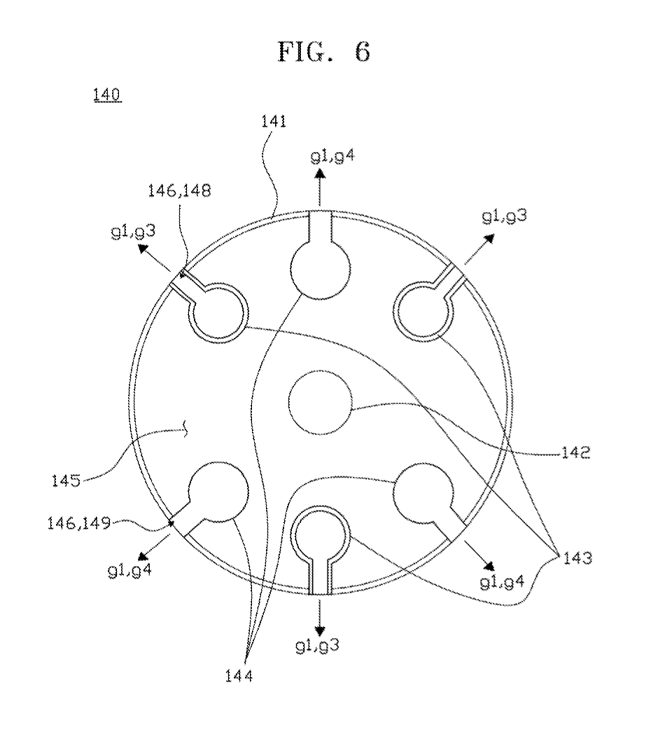

FIG. 4 is a perspective view of the process gas supplier 140 according to an embodiment of the present invention, FIG. 5 is a vertical cross-sectional view of the process gas supplier 140 of FIG. 4, and FIG. 6 is a horizontal cross-sectional view of the process gas supplier 140 of FIG. 4.

Referring to FIGS. 4 to 6, the process gas supplier 140 may have a multi-tube structure in which a first inner tube 142, second inner tubes 143, and third inner tubes 144 are included in an outer tube 141. Although the number of the second inner tubes 143 is three and the number of the third inner tubes 144 is also three according to the current embodiment of the present invention, the numbers of the second and third inner tubes 143 and 144 are not limited thereto and may be variously changed depending on purposes and uses thereof.

The outer tube 141 may provide a passage of a first process gas g1 (e.g., a nitriding gas such as an NH₃ gas). The first process gas g1 may be supplied from an external first process gas supplier (not shown) connected to a lower part of the process gas supplier 140, and may flow through an internal space 145 of the outer tube 141 other than spaces occupied by the first, second, and third inner tubes 142, 143, and 144. Then, the first process gas g1 may be supplied through one or more first gas injectors 146 provided on the outer circumferential surface of the outer tube 141, to a processing space outside the outer tube 141 (i.e., the chamber 110). The first gas injectors 146 may be configured as holes provided in the outer circumferential surface of the outer tube 141.

The first inner tube 142 may provide a passage of a second process gas g2 (e.g., a halogen-containing gas such as an HCl gas). The second process gas g2 may be supplied from an external second process gas supplier (not shown) connected to the lower part of the process gas supplier 140, and may flow through the first inner tube 142.

The first inner tube 142 may be located at the center of the outer tube 141 in such a manner that the second process gas g2 is supplied to a gas reactor 160 to be described below and a third process gas g3 passes through the second inner tubes 143 and is supplied through second gas injectors 148. In other words, the second process gas g2 may be supplied upward through the first inner tube 142 located at the center of the outer tube 141, and the third process gas g3 may be supplied downward from the gas reactor 160 toward the substrates 1 through the second inner tubes 143 surrounding the first inner tube 142 in the outer tube 141.

The second inner tubes 143 may provide passages of the third process gas g3 (e.g., a GaCl gas). The third process gas g3 may be supplied from the gas reactor 160 located at an upper side of the second inner tubes 143 (or the outer tube 141), and may flow through the second inner tubes 143. Then, the third process gas g3 may be supplied through the second gas injectors 148 to the processing space outside the outer tube 141 (i.e., the chamber 110). The second gas injectors 148 may be configured as tubes or nozzles having one-side ends connected to the second inner tubes 143 and another-side ends connected to the outer circumferential surface of the outer tube 141. Alternatively, if the second inner tubes 143 are located to contact the inner wall of the outer tube 141, the second gas injectors 148 may be configured as holes connected from the second inner tubes 143 to the outer circumferential surface of the outer tube 141.

The third inner tubes 144 may provide passages of a fourth process gas g4 (e.g., a doping gas such as a SiH₄ gas). The fourth process gas g4 may be supplied from an external fourth process gas supplier (not shown) connected to the lower part of the process gas supplier 140, and may flow through the third inner tubes 144. Then, the fourth process gas g4 may be supplied through one or more third gas injectors 149 provided on the outer circumferential surface of the outer tube 141, to the processing space outside the outer tube 141 (i.e., the chamber 110). The third gas injectors 149 may be configured as tubes or nozzles having one-side ends connected to the third inner tubes 144 and another-side ends connected to the outer circumferential surface of the outer tube 141. Alternatively, if the third inner tubes 144 are located to contact the inner wall of the outer tube 141, the third gas injectors 149 may be configured as holes connected from the third inner tubes 144 to the outer circumferential surface of the outer tube 141.

The number of each of the first, second, and third gas injectors 146, 148, and 149 is not particularly limited and may vary depending on the purposes of the embodiments.

The first, second, and third gas injectors 146, 148, and 149 may be located to correspond to the substrate supports 131. In other words, the first, second, and third gas injectors 146, 148, and 149 may be provided toward spaces between the substrates 1 stacked on one another in the processing space (i.e., the chamber 110) (or spaces between the susceptors 133) and thus the process gases g may be uniformly supplied.

In addition, as illustrated in FIG. 6, each of the first gas injectors 146 and each of the second gas injectors 148 may be provided toward the same direction. As such, the first process gas g1 (e.g., a nitriding gas) injected from the first gas injectors 146 and the third process gas g3 (e.g., a halogen gas) injected from the second gas injectors 148 may uniformly react with each other and thus epitaxial layers may be uniformly formed on the substrates 1.

Although the first process gas g1 is a nitriding gas such as an NH₃ gas, the second process gas g2 is a halogen-containing gas such as an HCl gas, the third process gas g3 is a metal halogen gas such as a GaCl gas, and the fourth process gas g4 is a doping gas such as a SiH₄ gas in the above description, the process gases g are not limited thereto. A metal source 163 to be described below may include at least one of gallium (Ga) and aluminum (Al). As such, the third process gas g3 may include at least one of metal halogen gases such as a GaCl gas, an AlCl gas, and an AlCl₃ gas, and the fourth process gas g4 may include at least one of doping gases such as a SiH₄ gas, a Si₂H₆ gas, and a SiH₂Cl₂ (dichlorosilane (DCS)) gas.

In addition, although three types of gases, e.g., the first process gas g1 serving as a nitriding gas, the third process gas g3 serving as a metal halogen gas, and the fourth process gas g4 serving as a doping gas, are supplied through the first, second, and third gas injectors 146, 148, and 149 in the above description, the gases are not limited thereto. For example, the first process gas g1 serving as a doping gas and the third process gas g3 serving as a nitriding gas may be supplied through the first and third gas injectors 146 and 149, respectively.

In the process gas supplier 140 according to the embodiment, since three types of process gases g1, g3, and g4 are injected through the first, second, and third gas injectors 146, 148, and 149, respectively, deposition of a deposition material on the inner wall of the process gas supplier 140 due to reaction of the process gases g1, g3, and g4 in the process gas supplier 140 before reaching the substrates 1 may be prevented. Furthermore, since three types of process gases g1, g3, and g4 are suppliable using a single process gas supplier 140, three separate process gas supply tubes are not necessary.

Referring further to FIG. 4, the gas reactor 160 may be located at an upper side of the outer tube 141. The halogen-containing gas supplied through the first inner tube 142 may react with the metal source 163 (e.g., a Ga source) and thus one of the process gases g, e.g., the third process gas g3, may be generated in the gas reactor 160. Accordingly, the third process gas g3 generated in the gas reactor 160 may be supplied downward through the second inner tubes 143 from an upper part of the process gas supplier 140.

The gas reactor 160 may include an inlet passage 161 for passing therethrough the second process gas g2 supplied from the first inner tube 142, a first connection passage 162a for passing therethrough the second process gas g2 supplied from the inlet passage 161, a second connection passage 162b connected to the first connection passage 162a, a metal source storage 166 for accommodating therein the metal source 163 reacting with the second process gas g2 passed through the second connection passage 162b, and an outlet passage 164 for supplying the third process gas g3 generated due to reaction between the metal source 163 and the second process gas g2, to the second inner tubes 143.

The second process gas g2 supplied upward through the first inner tube 142 of the supply gas supplier 140 may be supplied through the inlet passage 161 into the gas reactor 160. The second process gas g2 supplied into the gas reactor 160 may be supplied through the first and second connection passages 162a and 162b to the metal source 163. The gas reactor 160 may have a cylindrical shape, and the first and second connection passages 162a and 162b may be provided in such a manner that the second process gas g2 supplied from the inlet passage 161 located at the center of the supply gas generator 160 flows along outer edges of the supply gas generator 160 and reaches the metal source 163. Due to this configuration, compared to a case in which the second process gas g2 contacts the metal source 163 immediately after passing through the inlet passage 161, a contact area and time of the second process gas g2 on the metal source 163 may be increased. Therefore, according to the current embodiment of the present invention, the possibility that the second process gas g2 reacts with metal included in the metal source 163 to generate the third process gas g3 may be increased. In addition, since the metal source 163 is located in the chamber 110 which is maintained at a high temperature by the heater 120, an additional heater for maintaining a temperature for reaction between the second process gas g2 and the metal is not necessary, and the reaction temperature may be easily controlled.

The second process gas g2 supplied to the metal source 163 may react with the metal included in the metal source 163 to generate the third process gas g3, and the generated third process gas g3 may be supplied through the outlet passage 164 to the second inner tubes 143. The outlet passage 164 may be provided in the gas reactor 160 to allow the generated third process gas g3 to flow toward the second inner tubes 143. Since the outlet passage 164 is located in the chamber 110, liquefaction or condensation of the third process gas g3 in the outlet passage 164 may be prevented. The third process gas g3 may flow downward through the second inner tubes 143 and may be injected through the second gas injectors 148 onto the substrates 1.

Meanwhile, the gas reactor 160 may include a block 165 to provide the inlet passage 161, the first connection passage 162a, the second connection passage 162b, and the outlet passage 164. That is, the block 165 may be provided in the gas reactor 160 to form gaps between the inner surface of the gas reactor 160 and the block 165, and the gaps may serve as the inlet passage 161, the first connection passage 162a, the second connection passage 162b, and the outlet passage 164 based on the locations thereof.

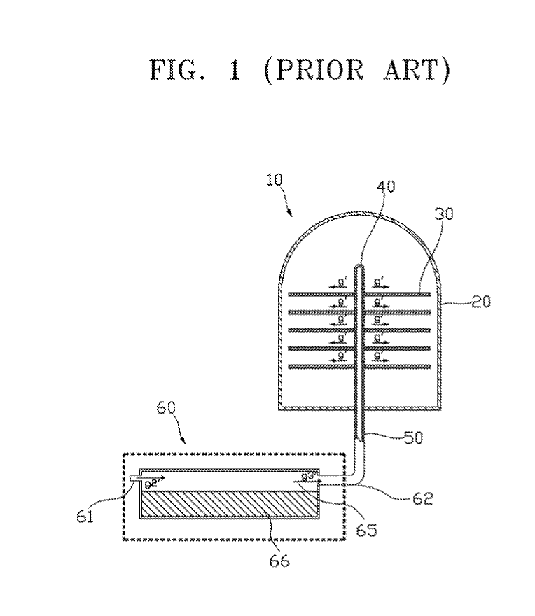

According to the embodiment, the metal source 163 for generating the third process gas g3 and the outlet passage 164 for supplying the third process gas g3 to the process gas supplier 140 may be located in the chamber 110. Therefore, unlike the conventional deposition layer forming apparatus 10 (see FIG. 1) in which the additional metal halogen gas generator 60 is located outside the chamber 20, an additional heater for maintaining a reaction temperature of the metal source 163 is not necessary, the reaction temperature of the metal source 163 may be easily controlled, and liquefaction or condensation of the third process gas g3 flowing through the outlet passage 164 due to a low temperature may be prevented. Therefore, the third process gas g3 may be stably supplied from the process gas supplier 140. Furthermore, since the additional metal halogen gas generator 60 (see FIG. 1) is not necessary, an apparatus size may be reduced.

As described above, according to the embodiments, epitaxial layers may be uniformly formed on a plurality of substrates.

Furthermore, process gases may be stably supplied and an apparatus size may be reduced.

In addition, three types of gases may be simultaneously supplied.

Besides, process gases may be supplied to achieve a uniform reaction rate.

While the present invention has been particularly shown and described with reference to embodiments thereof, it will be understood by those of ordinary skill in the art that various changes in form and details may be made therein without departing from the spirit and scope of the present invention as defined by the following claims.

What is claimed is:

1. A process gas supplier comprising:
an outer tube providing a passage for a first process gas;
a first inner tube located in the outer tube and providing a passage for a second process gas;
a gas reactor located at an upper part of the outer tube, accommodating a metal source and generating a third process gas by a reaction between the second process gas and the metal source;
a second inner tube located in the outer tube and providing a passage for the third process gas;
a third inner tube located in the outer tube and providing a passage for a fourth process gas;
one or more first gas injectors supplying the first process gas flowing in the outer tube, to a processing space outside the outer tube;
one or more second gas injectors supplying the third process gas flowing in the second inner tube, to the processing space; and
one or more third gas injectors supplying the fourth process gas flowing in the third inner tube, to the processing space.

2. The process gas supplier of claim 1,
wherein the first, second, and third gas injectors are provided to face spaces between a plurality of substrates stacked in the processing space.

3. The process gas supplier of claim 2,
wherein the first and second gas injectors are provided along the same direction.

4. The process gas supplier of claim 1,
wherein the first inner tube is located at a center of the outer tube.

5. The process gas supplier of claim 1,
wherein the second and third gas injectors are communicatively connected to an outer circumferential surface of the outer tube.

6. The process gas supplier of claim 4,
wherein an upper end of the first inner tube is communicatively connected to a lower surface of the gas reactor.

7. The process gas supplier of claim 1,
wherein the first process gas is a nitriding gas,
wherein the second process gas is a halogen-containing gas,
wherein the third process gas is a metal halogen gas, and
wherein the fourth process gas is a doping gas.

8. The process gas supplier of claim 7,
wherein the nitriding gas is an NH₃ gas,
wherein the halogen-containing gas is an HCl gas,
wherein the metal source comprises at least one of gallium (Ga) and aluminum (Al),
wherein the metal halogen gas comprises at least one of a GaCl gas, an AlCl gas, and an AlCl₃ gas, and
wherein the doping gas comprises at least one of a SiH₄ gas, a Si₂H₆ gas, and a dichlorosilane (DCS; SiH₂Cl₂) gas.
